(19) United States
(12) Patent Application Publication
(10) Pub. No.: US 2007/0272436 A1
(43) Pub. Date: Nov. 29, 2007

(54) Printed circuit board unit

(75) Inventor: Akiko Matsui, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/528,349

(22) Filed: Sep. 28, 2006

(30) Foreign Application Priority Data
May 24, 2006 (JP) 2006-144702

(51) Int. Cl. H05K 1/16

(52) U.S. Cl. 174/260

(57) ABSTRACT

A depression is formed in a first surface of a printed wiring board. A through hole penetrates through the printed wiring board from the bottom surface of the depression to a second surface of the printed wiring board. The second surface is the opposite surface of the first surface. A terminal of an electronic component is received in the through hole. The terminal has the tip end protruding from the second surface of the printed wiring board. Solder is filled in the through hole. The tip end of the terminal is allowed to protrude from the second surface of the printed wiring board even when the terminal is shorter than the original thickness of the printed wiring board. It is not necessary to change the length of the terminal.

### BACKGROUND OF THE INVENTION

1. Field of the Invention

The present invention relates to a printed circuit board unit. In particular, the printed circuit board unit includes: a printed wiring board; a through hole penetrating through the printed wiring board from a first surface of the printed wiring board to a second surface of the printed wiring board, the second surface being the opposite surface of the first surface; an electronic component located on the first or second surface of the printed wiring board; and a terminal attached to the electronic component, the terminal penetrating through the through hole.

2. Description of the Prior Art

An electronic component is mounted on the back surface of a printed wiring board, for example, as disclosed in Japanese Patent Application Publication No. 1-238091. The terminals or leads of the electronic component are received in through holes defined in the printed wiring board, respectively. The tip end of the lead is located within a depression formed in the front surface of the printed wiring board. The tip end of the lead is bent within the depression. The depression is filled with solder. The lead is in this manner electrically coupled to the through hole.

The electronic component is a standard product. The lead is designed to have a standard length. The printed wiring board recently tends to include an increased number of layers. This causes an increase in the thickness of the printed wiring board. When the lead is not sufficiently long, the tip end of the lead cannot be bent. Accordingly, a change in the length of the lead is required. A change in the design of the standard product causes an increase in the production cost. Furthermore, it takes time to bend the lead.

### SUMMARY OF THE INVENTION

It is accordingly an object of the present invention to provide a printed circuit board unit allowing a terminal and a through hole coupled to each other with a sufficient strength without any change in the length of the terminal.

According to a first aspect of the present invention, there is provided a printed circuit board unit comprising: a printed wiring board; a depression formed in a first surface of the printed wiring board; a through hole formed in the printed wiring board, the through hole penetrating through the printed wiring board from the bottom surface of the depression to a second surface of the printed wiring board, the second surface being the opposite surface of the first surface; an electronic component received in the depression; a terminal attached to the electronic component, the terminal received in the through hole, the terminal having the tip end protruding from the second surface of the printed wiring board; and solder filled in the through hole, the solder forming a fillet on the second surface of the printed wiring board at a periphery of the terminal.

The printed circuit board unit allows a partial reduction in the thickness of the printed wiring board based on the establishment of the depression. The tip end of the terminal is thus allowed to protrude from the second surface of the printed wiring board even when the terminal is shorter than the original thickness of the printed wiring board. It is not necessary to change the length of the terminal. Furthermore, the solder forms the fillet at the periphery of the terminal. The fillet serves to ensure a higher bonding strength between the solder and the through hole. The terminal is thus coupled to the through hole with a sufficient strength. This results in a reliable avoidance of detachment of the electronic component from the printed wiring board. The printed circuit board unit may be incorporated in an electronic apparatus or the like.

The printed circuit board unit may further comprise a through hole land formed in the printed wiring board at the periphery of the through hole. Likewise, the printed circuit board unit may further comprise a through hole land formed on the bottom surface of the depression at the periphery of the through hole. The through hole land or lands serve to ensure a stronger coupling between the through hole and the printed wiring board. A so-called anchoring effect is realized. Even when a load is applied to the terminal in the axial direction of the through hole, the solder and the through hole are prevented from separation from the printed wiring board. This results in a reliable avoidance of detachment of the electronic component from the printed wiring board.

A specific printed wiring board is provided to realize the printed circuit board unit. The specific printed wiring board may comprise: a substrate; a depression formed in a first surface of the substrate, the depression having a dimension large enough to receive an electronic component; and a through hole penetrating through the substrate from the bottom surface of the depression to a second surface of the substrate, the second surface being the opposite surface of the first surface, the through hole allowing the tip end of a terminal of the electronic component to protrude from the second surface.

The printed wiring board may further comprise a through hole land formed in the substrate at the periphery of the through hole in the same manner as described above. Likewise, the printed wiring board may further comprise a through hole land formed on the bottom surface of the depression at the periphery of the through hole.

According to a second aspect of the present invention, there is provided a printed circuit board unit comprising: a printed wiring board; an electronic component located on a first surface of the printed wiring board; a depression or depressions formed in a second surface of the printed wiring board, the second surface being the opposite surface of the first surface; a through hole or holes penetrating through the printed wiring board from the first surface of the printed wiring board to the bottom surface or surfaces of the depression or depressions; a terminal or terminals attached to the electronic component, the terminal or terminals received in the through hole or holes, the terminal or terminals having the tip end or ends protruding straight into the depression or depressions; and solder filled in the through hole or holes, the solder forming a fillet or fillets on the bottom surface or surfaces of the depression or depressions around the terminal or terminals.

The printed circuit board unit allows a partial reduction in the thickness of the printed wiring board based on the establishment of the depression in the same manner as described above. The tip end of the terminal can thus be located within the depression or depressions even when the terminal or terminals are shorter than the original thickness of the printed wiring board. It is not necessary to change the length of the terminal or terminals. In addition, the solder forms the fillet at the periphery of the terminal or terminals. The fillet serves to ensure a higher bonding strength between the solder and the through hole. The terminal or terminals are thus coupled to the printed wiring board with a sufficient strength. This results in a reliable avoidance of detachment of the electronic component from the printed wiring board. The printed circuit board unit may be incorporated in an electronic apparatus or the like.

In this case, the depression may correspond to a corresponding one of the terminals in the printed circuit board unit. The area of the depressions can be reduced as compared with the depression having the contour corresponding to the projection image of the electronic component, for example. Not only the depressions enable a partial reduction in the thickness of the printed wiring board, but also the depressions contribute to a reduction in loss of a space for a wiring pattern, an electrically conductive layer, and the like, in the printed wiring board.

Alternatively, the depression may correspond to a group of corresponding ones of the terminals. The area of the depressions can be reduced as compared with the depression having the contour corresponding to the projection image of the electronic component, for example. Not only the depressions enable a partial reduction in the thickness of the printed wiring board, but also the depressions contribute to a reduction in loss of a space for a wiring pattern, an electrically conductive layer, and the like, in the printed wiring board.

### BRIEF DESCRIPTION OF THE DRAWINGS

The above and other objects, features and advantages of the present invention will become apparent from the following description of the preferred embodiments in conjunction with the accompanying drawings, wherein:

FIG. 1 is a perspective view schematically illustrating a server computer as a specific example of an electronic apparatus according to the present invention;

FIG. 2 is an enlarged partial perspective view schematically illustrating a printed circuit board unit according to a first embodiment of the present invention;

FIG. 3 is a sectional view taken along the line 3-3 in FIG. 2;

FIG. 4 is a sectional view schematically illustrating a process of forming through bores, through holes, through hole lands and a wiring pattern in a printed wiring board;

FIG. 5 is a sectional view schematically illustrating a process of forming a depression in the printed wiring board;

FIG. 6 is a sectional view schematically illustrating a process of filling the through holes with solder;

FIG. 7 is a sectional view schematically illustrating a printed circuit board unit according to a second embodiment of the present invention;

FIG. 8 is a sectional view schematically illustrating a printed circuit board unit according to a third embodiment of the present invention;

FIG. 9 is a sectional view schematically illustrating a process of forming through bores, through holes, through hole lands and a wiring pattern in a printed wiring board;

FIG. 10 is a sectional view schematically illustrating a process of hollowing the printed wiring board to a predetermined depth;

FIG. 11 is a sectional view schematically illustrating a printed circuit board unit according to a fourth embodiment of the present invention;

FIG. 12 is a bottom view schematically illustrating a depression formed in the back surface of a printed wiring board;

FIG. 13 is a bottom view schematically illustrating depressions formed in the back surface of a printed wiring board; and

FIG. 14 is a bottom view schematically illustrating depressions formed in the back surface of a printed wiring board.

### DESCRIPTION OF THE PREFERRED EMBODIMENTS

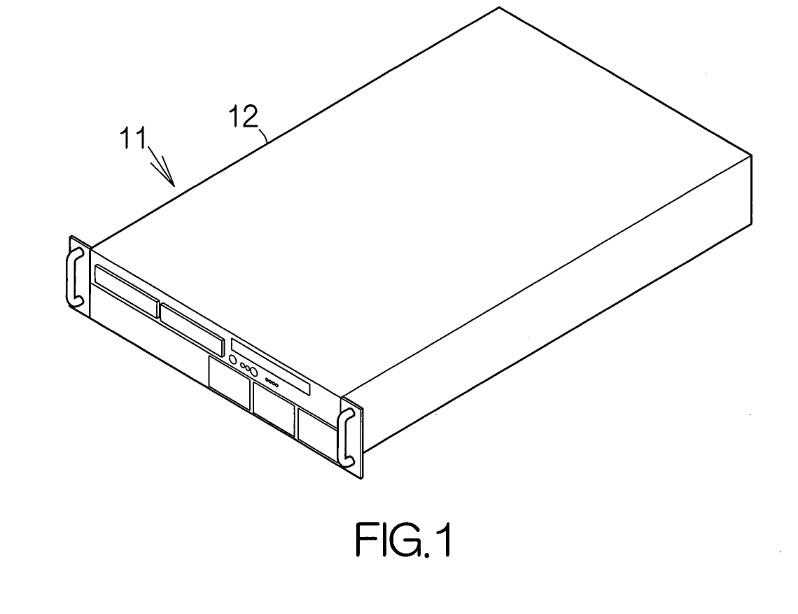

FIG. 1 schematically illustrates a server computer 11 as a specific example of an electronic apparatus according to an embodiment of the present invention. The server computer 11 is mounted on a rack, for example. The server computer 11 includes an enclosure 12. A printed circuit board unit or main board unit is enclosed in the enclosure 12.

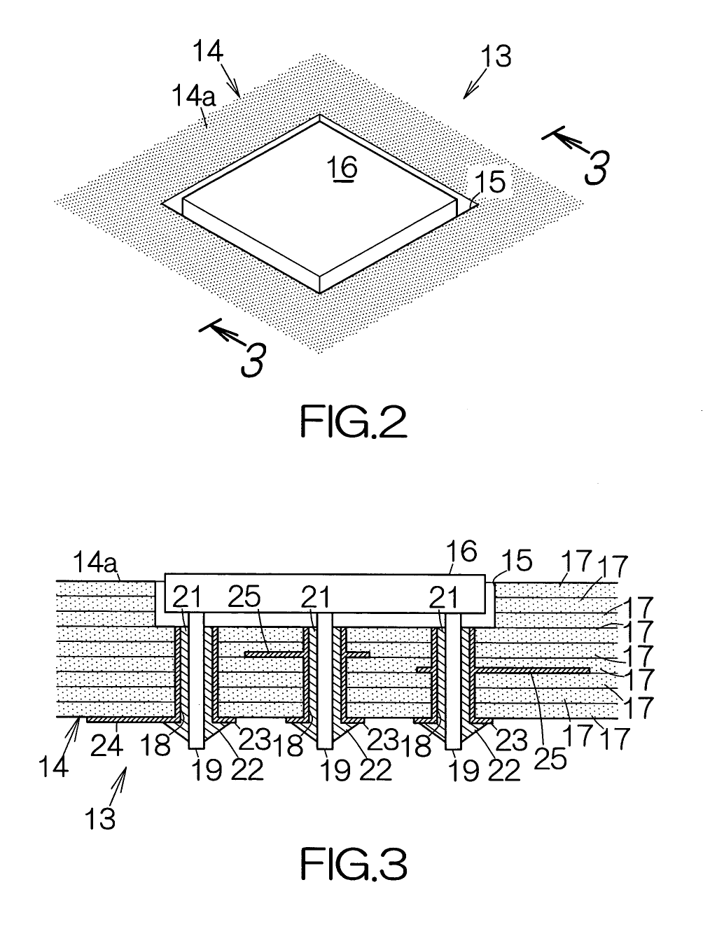

As shown in FIG. 2, the main board unit 13 includes a printed wiring board 14. The printed wiring board 14, includes a substrate 14a. A depression 15 is formed in the front surface of the substrate 14a. The depression 15 forms a space in the shape of a rectangular parallelepiped, for example. An electronic component or large-scale integrated circuit (LSI) chip 16 is received in the depression 15. The LSI chip 16 is a so-called insert mounting device (IMD).

As shown in FIG. 3, the substrate 14a has a layered structure including insulating layers 17. The insulating layer 17 may be made of a resin material, for example. A through hole or holes 18 are, for example, formed in the substrate 14a. The through holes 18 are designed to penetrate through the substrate 14a from the bottom surface of the depression 15 to the back surface of the substrate 14a.

The individual through hole 18 accepts insertion of a terminal or electrode pin 19 attached to the bottom surface of the LSI chip 16, for example. The electrode pin 19 is designed to extend straight in the vertical direction perpendicular to the bottom surface of the LSI chip 16, for example. The tip end of the electrode pin 19 protrudes from the back surface of the substrate 14a at the extension of the through hole 18. Here, the electrode pin 19 may slightly be exposed between the LSI chip 16 and the upper end of the through hole 18.

The individual through hole 18 is filled with a piece of solder 21. The solder 21 spreads in a space between the opposite ends of the through hole 18 without any gap. The solder 21 forms a fillet 22 on the back surface of the substrate 14a at the periphery of the electrode pin 19. The solder 21 serves to bond the electrode pin 19 to the through hole 18. The LSI chip 16 is in this manner mounted on the substrate 14a.

A through hole land 23 is formed on the back surface of the substrate 14a at the periphery of the individual through hole 18. A wiring pattern 24 may be connected to the through hole land 23. The wiring pattern 24 may extend along the back surface of the substrate 14a. The through hole land 23 and the wiring pattern 24 may be made of an electrically conductive material such as copper, for example.

Electrically conductive layers 25, such as a power supply layer or layers, a ground layer or layers and a signal layer or layers, are formed on the surfaces of the insulating layers 17. The electrically conductive layers 25 are connected to the through holes 18, for example. An electrical connection is thus established between the electrically conductive layers 25 and the LSI chip 16. The electrically conductive layers 25 may be made of an electrically conducive material such as copper, for example.

The depression 15 allows a partial reduction in the thickness of the substrate 14a in the main board unit 13. The tip end of the electrode pin 19 is thus allowed to protrude from the back surface of the substrate 14a even when the electrode pins 19 are shorter than the original thickness of the substrate 14a. It is not necessary to change the length of the electrode pins 19.

Furthermore, the solder 21 forms the fillet 22 around the individual electrode pin 19. The fillet 21 serves to ensure a higher bonding strength between the solder 21 and the through hole 18. The electrode pin 19 is thus coupled to the substrate 14a with a sufficient strength. This results in a reliable avoidance of detachment of the LSI chip 16 from the substrate 14a.

A brief description will be made on a method of making the main board unit 13. As shown in FIG. 4, a through bore or bores 26 are, for example, formed in the substrate 14a. Plating is effected to form the through hole 18 on the inside surface of the individual through bore 26. Simultaneously, the through hole lands 23 and the wiring pattern 24 are formed on the front and back surfaces of the substrate 14a. The through holes 18 are connected to the electrically conductive layers 25. The electrically conductive layers 25 have previously been formed in the substrate 14a.

The depression 15 is formed in the front surface of the substrate 14a. Milling process may be effected to form the depression 15, for example. As shown in FIG. 5, the insulating layers 17 are hollowed to a predetermined depth from the front surface of the substrate 14a. The LSI chip 16 is then inserted into the depression 15. The individual through hole 18 accepts the insertion of the electrode pin 19. The tip end of the electrode pin 19 protrudes from the back surface of the substrate 14a.

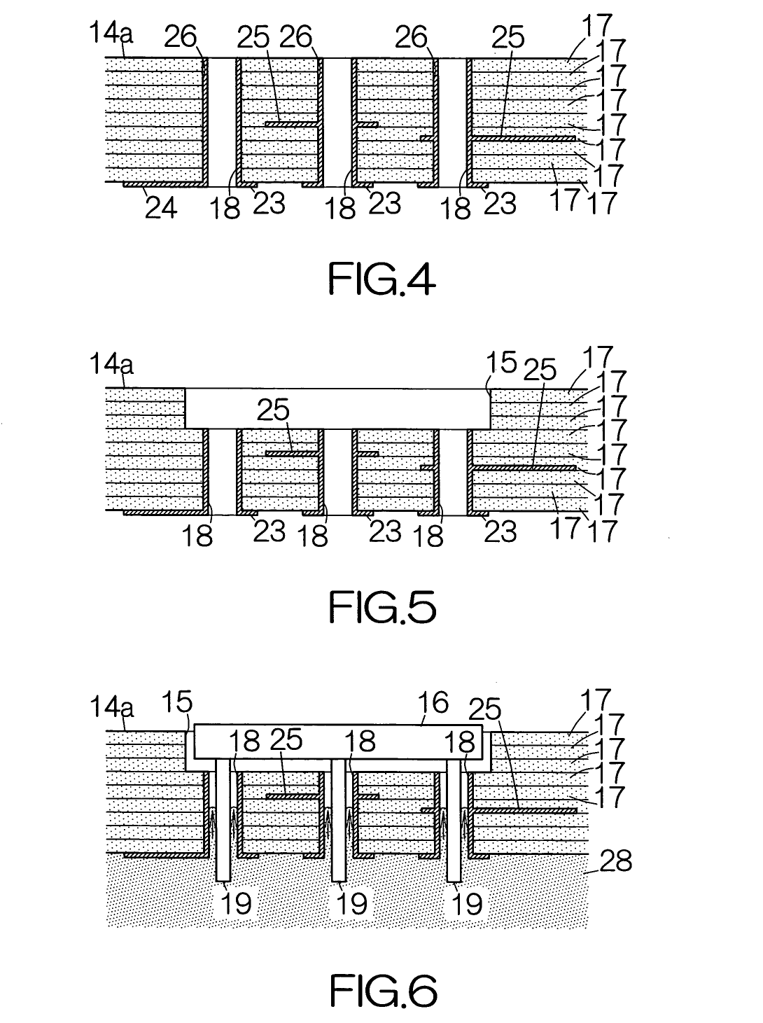

As shown in FIG. 6, the back surface of the substrate 14a is exposed to a spout of solder 28 in the fluid state in a solder bath. The solder 28 in the fluid state enters the individual through hole 18 from the back surface of the substrate 14a. The solder 28 goes up to the upper end of the individual through hole 18 with the assistance of the capillary action. The through holes 18 are in this manner filled with the solder 28. The substrate 14a is then taken out of the solder bath.

Here, the solder 28 fills a space between the inside surface of the individual through hole 18 and the outer surface of the electrode pin 19 with the assistance of the capillary action. The longer a through hole gets, the smaller the diameter of the through hole must get to exhibit a sufficient capillary action. A reduction in the diameter of the through hole 18 causes a difficulty in the insertion of the electrode pin 19 into the through hole 18. Accordingly, the diameter of the through hole 18 may be set sufficiently larger than that of the electrode pin 19.

The solder 28 gets solidified in the substrate 14a. The solder 28 continuously spreads in a space between the opposite ends of the through hole 18 without any gap. Simultaneously, the solder 28 forms the aforementioned fillet 22 on the back surface of the substrate 14a around the electrode pin 19. A reduction in the thickness of the substrate 14a leads to a reduction in the length of the through hole 18. The through hole 18 can thus reliably be filled with the solder 28.

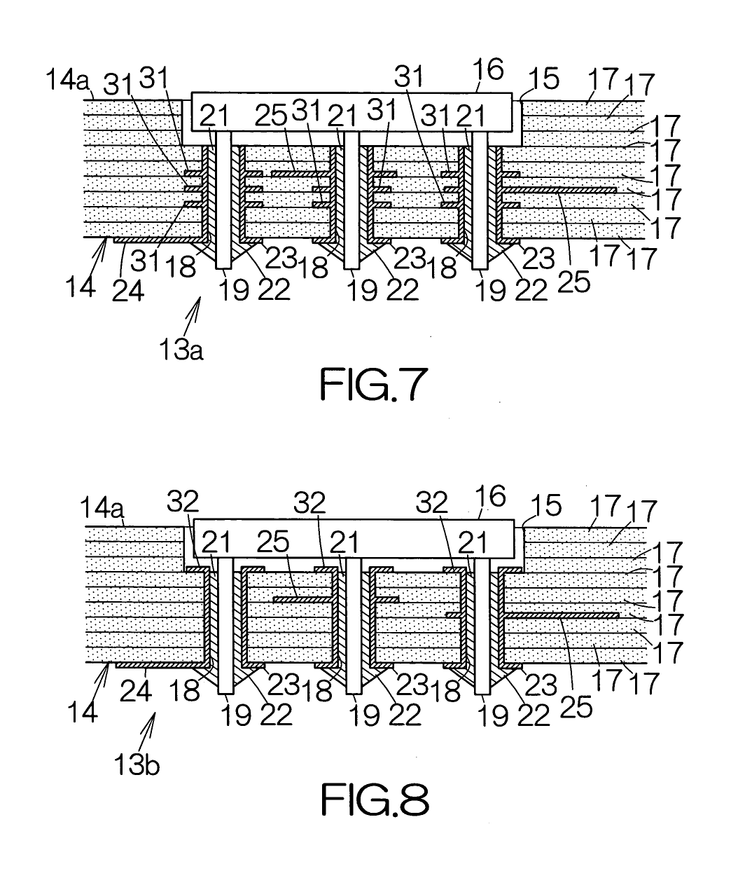

FIG. 7 schematically illustrates a main board unit 13a according to a second embodiment of the present invention. The main board unit 13a includes through hole lands 31 formed inside the substrate 14a, in addition to the structure of the aforementioned main board unit 13. The through hole lands 31 are connected to the through holes 18. The through hole lands 31 are isolated from electrically-conductive layers such as a power supply layer or layers, a ground layer or layers and a signal layer or layers, not shown, likewise formed inside the substrate 14a. Like reference numerals are attached to the structure or components equivalent to those of the aforementioned first embodiment.

The through hole lands 31 inside the substrate 14a are connected to the through holes 18 in the main board unit 13a. This structure ensures a strong coupling between the through holes 18 and the substrate 14a. The through hole lands 31 serves to realize a so-called anchoring effect. Even when a load is applied to the electrode pin 19 in the axial direction of the through hole 18, the solders 21 and the through holes 18 are prevented from separation from the substrate 14a. This results in a reliable avoidance of detachment of the LSI chip 16 from the substrate 14a.

The aforementioned method may be employed to make the main board unit 13a. It should be noted that the through hole lands 31 may be formed on the surfaces of the insulating layers 17 prior to establishment of the substrate 14a. The through bores 26, the through holes 18, the through hole lands 23 and the wiring pattern 24 may subsequently be formed in the substrate 14a in the aforementioned manner. The through hole lands 31 are thus connected to the through holes 18.

FIG. 8 schematically illustrates a main board unit 13b according to a third embodiment of the present invention. The main board unit 13b includes through hole lands 32 in addition to the structure of the aforementioned main board unit 13. The through hole lands 32 are formed on the bottom surface of the depression 15 at the periphery of the through holes 18, respectively. The through hole lands 32 are connected to the through holes 18, respectively. The through hole lands 31 are isolated from electrically-conductive layers such as a power supply layer or layers, a ground layer or layers and a signal layer or layers, not shown, formed inside the substrate 14a. Like reference numerals are attached to the structure or components equivalent to those of the aforementioned first embodiment.

The through hole lands 32 are connected to the through holes 18 on the bottom surface of the depression 15 in the main board unit 13b. This structure ensures a strong coupling between the through holes 18 and the substrate 14a. The through hole lands 32 serves to realize a so-called anchoring effect. Even when a load is applied to the electrode pins 19 in the axial direction of the through holes 18, the solders 21 and the through holes 18 are prevented from separation from the substrate 14a. This results in a reliable avoidance of detachment of the LSI chip 16 from the substrate 14a.

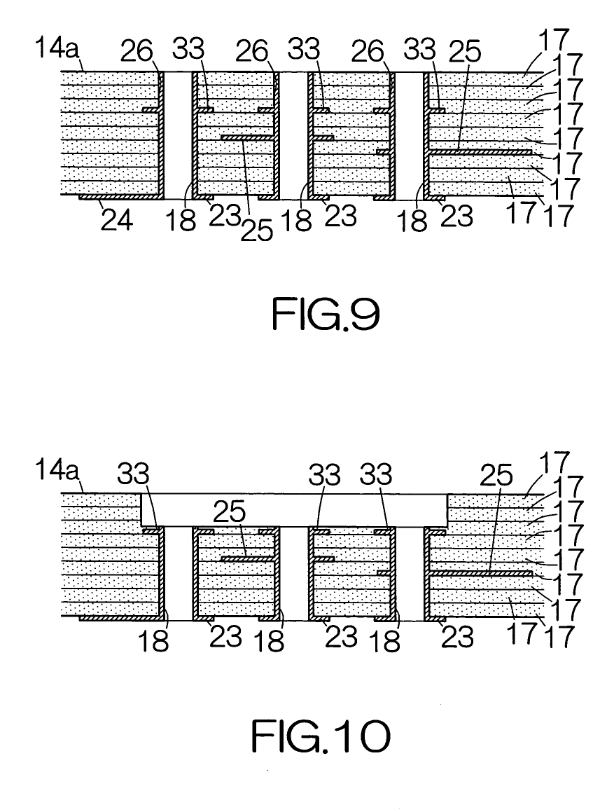

The aforementioned method may be employed to make the main board unit 13b. It should be noted that electrically conductive layers 33 may be formed on the surfaces of the insulating layers 17 prior to establishment of the substrate 14a, as shown in FIG. 9. Milling process is subsequently effected for hollowing the insulating layers 17 to a predetermined depth from the surface of the substrate 14a, for example. Exposure of the electrically conductive layers 33 is avoided at completion of the milling process, as shown in FIG. 10.

The insulating layer or layers 17 are then subjected to irradiation of a laser beam. A laser is employed to remove a resin material, namely the insulating layer or layers 17. The electrically conductive layers 33 are allowed to remain on the surface of the insulating layer or layers 17. The electrically conductive layers 33 serve as the through hole lands 32. The depression 15 is formed in this manner. The LSI chip 16 is then inserted into the depression 15 in the aforementioned manner. The main board unit 13b is realized in this manner.

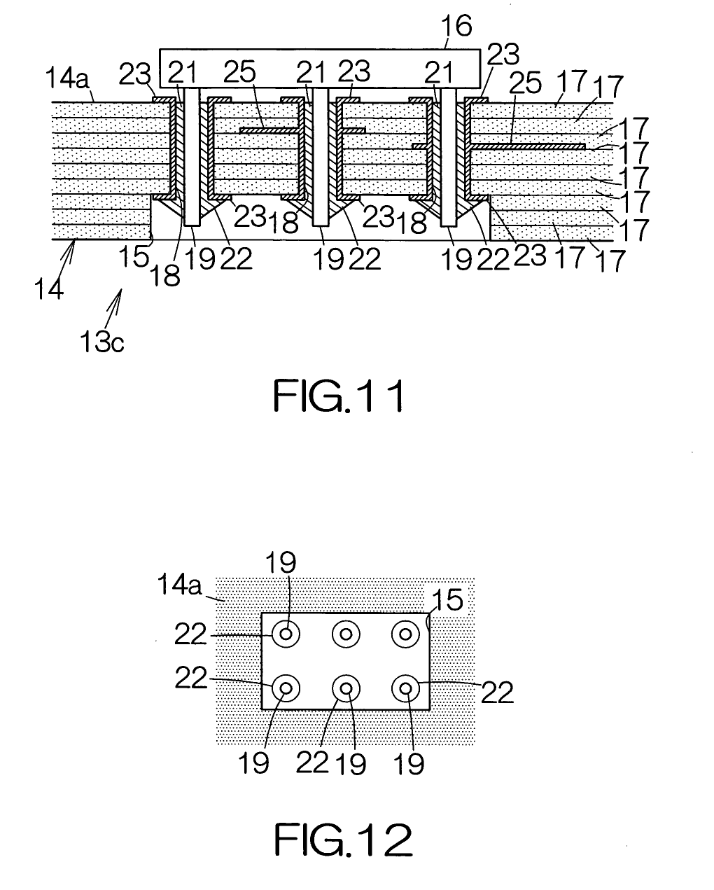

FIG. 11 schematically illustrates a main board unit 13c according to a fourth embodiment of the present invention. The depression 15 is formed in the back surface of the substrate 14a in the main board unit 13c. The tip ends of the electrode pins 19 protrude into the depression 15 at the extensions of the through holes 18. The electrode pins 19 are designed to extend straight in the vertical direction perpendicular to the bottom surface of the LSI chip 16, for example. The through hole lands 23 are formed at the periphery of the through holes 18 on the front surface of the substrate 14a and the bottom surface of the depression 15, respectively.

Electrode pins 19, six of those, for example, are attached to the LSI chip 16, as shown in FIG. 12. The depression 15 may have the contour corresponding to the projection image of the LSI chip 16, for example. Here, the tip ends of all the six electrode pins 19 may be located within the depression 15. Like reference numerals are attached to the structure or components equivalent to those of the aforementioned first to third embodiments.

The depression 15 allows a partial reduction in the thickness of the substrate 14a in the main board unit 13c in the same manner as described above. The tip ends of the electrode pins 19 are thus allowed to protrude into the depression 15 even when the electrode pins 19 are shorter than the original thickness of the substrate 14a. It is not necessary to change the length of the electrode pins 19.

Furthermore, the solder 21 forms the fillet 22 around the individual electrode pin 19. The fillet 21 serves to ensure a higher bonding strength between the solder 21 and the through hole 18. The electrode pin 19 is thus coupled to the substrate 14a with a sufficient strength. This results in a reliable avoidance of detachment of the LSI chip 16 from the substrate 14a.

The through holes 18, the through hole lands 23 and the electrically conductive layers 33 are formed in the substrate 14a to make the main board unit 13c in the same manner as the main board unit 13a according to the second embodiment. The depression 15 is subsequently formed in the back surface of the substrate 14a. Milling process and a process with a laser may be effected to form the depression 15. The insulating layers 17 are hollowed on the lower surface of the substrate 14a. The electrically conductive layers 33 or through hole lands 23 are allowed to remain on the bottom surface of the depression 15.

The LSI chip 16 is located on the front surface of the substrate 14a. The electrode pins 19 are received in the through holes 18, respectively. The tip ends of the electrode pins 19 are located within the depression 15. The back surface of the substrate 14a is exposed to a spout of the solder 28 in the fluid state in a solder bath. The solder 28 in the fluid state thus enters the individual through hole 18. The solder 28 goes up to the upper end of the individual through hole 18. The through holes 18 are in this manner filled with the solder 28. The fillet 22 is formed on the depression 15 at the periphery of the individual electrode pin 19.

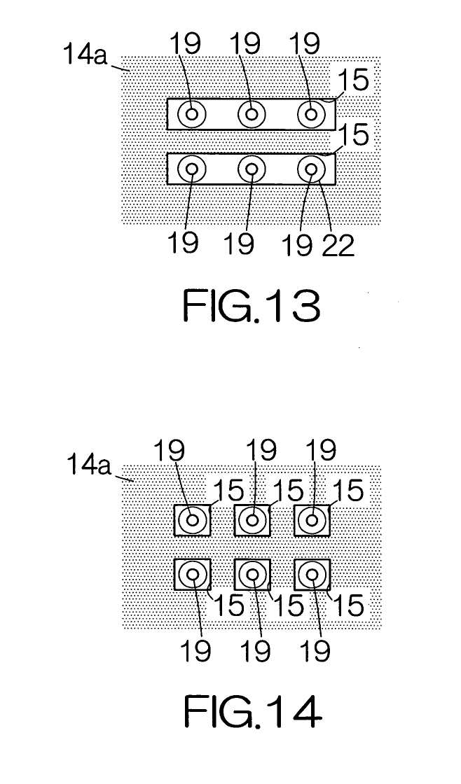

As shown in FIG. 13, the depression 15 may be allocated to a row of electrode pins 19, for example. In this case, the area of the depressions 15 may be reduced as compared with the aforementioned depression 15 having the contour corresponding to the projection image of the LSI image 16. Not only the depressions 15 enable a partial reduction in the thickness of the substrate 14a, but also the depressions 15 contribute to a reduction in loss of a space for wiring patterns, electrically conductive layers, and the like, in the substrate 14a.

As shown in FIG. 14, the depression 15 may be allocated to a single one of the electrode pins 19, for example. In this case, the area of the depressions 15 may further be reduced as compared with the aforementioned depressions 15 allocated to the groups of the electrode pins 19. Not only the depressions 15 enable a partial reduction in the thickness of the substrate 14a, but also the depressions 15 contribute to a reduction in loss of a space for wiring patterns, electrically conductive layers, and the like, in the substrate 14a.

The depression or depressions 15 may be formed when the substrate 14a is formed. Specifically, an opening or openings may be formed in the insulating layer or layers 17 to reflect the contour or contours of the depression or depressions 15. The insulating layers 17 each defining the opening or openings may be coupled to one another. This results in establishment of the depression or depressions 15 in the substrate 14a.

What is claimed is:

1. A printed circuit board unit comprising:
a printed wiring board;
a depression formed in a first surface of the printed wiring board;
a through hole formed in the printed wiring board, said through hole penetrating through the printed wiring board from a bottom surface of the depression to a second surface of the printed wiring board, said second surface being an opposite surface of the first surface;
an electronic component received in the depression;
a terminal attached to the electronic component, said terminal received in the through hole, said terminal having a tip end protruding from the second surface of the printed wiring board; and
solder filled in the through hole, said solder forming a fillet on the second surface of the printed wiring board at a periphery of the terminal.

2. The printed circuit board unit according to claim 1, further comprising a through hole land formed in the printed wiring board at a periphery of the through hole.

3. The printed circuit board unit according to claim 1, further comprising a through hole land formed on the bottom surface of the depression at a periphery of the through hole.

4. A printed circuit board unit comprising:
a printed wiring board;
an electronic component located on a first surface of the printed wiring board;
a depression or depressions formed in a second surface of the printed wiring board, said second surface being an opposite surface of the first surface;
a through hole or holes penetrating through the printed wiring board from the first surface of the printed wiring board to a bottom surface or surfaces of the depression or depressions;
a terminal or terminals attached to the electronic component, said terminal or terminals received in the through hole or holes, said terminal or terminals having a tip end or ends protruding straight into the depression or depressions; and
solder filled in the through hole or holes, said solder forming a fillet or fillets on the bottom surface or surfaces of the depression or depressions around the terminal or terminals.

5. The printed circuit board unit according to claim 4, wherein the depression corresponds to a corresponding one of the terminals.

6. The printed circuit board unit according to claim 4, wherein the depression corresponds to a group of corresponding ones of the terminals.

7. A printed wiring board comprising:
a substrate;
a depression formed in a first surface of the substrate, said depression having a dimension large enough to receive an electronic component; and
a through hole penetrating through the substrate from a bottom surface of the depression to a second surface of the substrate, said second surface being an opposite surface of the first surface, said through hole allowing a tip end of a terminal of the electronic component to protrude from the second surface.

8. The printed wiring board according to claim 7, further comprising a through hole land formed in the substrate at a periphery of the through hole.

9. The printed wiring board according to claim 7, further comprising a through hole land formed on the bottom surface of the depression at a periphery of the through hole.

10. An electronic apparatus including a printed circuit board unit, said printed circuit board unit comprising:
a printed wiring board;
a depression formed in a first surface of the printed wiring board;
a through hole formed in the printed wiring board, said through hole penetrating through the printed wiring board from a bottom surface of the depression to a second surface of the printed wiring board, said second surface being an opposite surface of the first surface;
an electronic component received in the depression;
a terminal attached to the electronic component, said terminal received in the through hole, said terminal having a tip end protruding from the second surface of the printed wiring board; and
solder filled in the through hole, said solder forming a fillet on the second surface of the printed wiring board at a periphery of the terminal.

11. The electronic apparatus according to claim 10, further comprising a through hole land formed in the printed wiring board at a periphery of the through hole.

12. The electronic apparatus according to claim 10, further comprising a through hole land formed on the bottom surface of the depression at a periphery of the through hole.

13. An electronic apparatus including a printed circuit board unit, said printed circuit board unit comprising:
a printed wiring board;
an electronic component located on a first surface of the printed wiring board;
a depression or depressions formed in a second surface of the printed wiring board, said second surface being an opposite surface of the first surface;
a through hole or holes penetrating through the printed wiring board from the first surface of the printed wiring board to a bottom surface or surfaces of the depression or depressions;
a terminal or terminals attached to the electronic component, said terminal or terminals received in the through hole or holes, said terminal or terminals having a tip end or ends protruding straight into the depression or depressions; and
solder filled in the through hole or holes, said solder forming a fillet or fillets on the bottom surface or surfaces of the depression or depressions around the terminal or terminals.

14. The electronic apparatus according to claim 13, wherein the depression corresponds to a corresponding one of the terminals.

15. The electronic apparatus according to claim 13, wherein the depression corresponds to a group of corresponding ones of the terminals.
